(19) United States
(12) Patent Application Publication
(10) Pub. No.: US 2019/0363198 A1
(43) Pub. Date: Nov. 28, 2019

(54) GALLIUM-NITRIDE-BASED TRANSCAPS FOR MILLIMETER WAVE APPLICATIONS

(71) Applicant: QUALCOMM Incorporated, San Diego, CA (US)

(72) Inventors: Gengming TAO, San Diego, CA (US); Xia LI, San Diego, CA (US); Bin YANG, San Diego, CA (US); Periannan CHIDAMBARAM, San Diego, CA (US)

(21) Appl. No.: 15/990,229

(22) Filed: May 25, 2018

(51) Int. Cl. H01L 29/94; H01L 29/20; H01L 29/205; H01L 29/66

(52) U.S. Cl. CPC H01L 29/94; H01L 29/2003; H03B 5/08; H01L 29/66189; H01L 29/205

(57) ABSTRACT

Certain aspects of the present disclosure provide a semiconductor variable capacitor. The semiconductor variable capacitor generally includes a first semiconductor region having a first doping type, a second semiconductor region having a second doping type different from the first doping type, a third semiconductor region disposed between the first semiconductor region and the second semiconductor region, a first terminal disposed adjacent to the first semiconductor region, a second terminal disposed adjacent to the second semiconductor region, and a third terminal disposed above the third semiconductor region. The first semiconductor region, the second semiconductor region, and/or the third semiconductor region include gallium nitride. The third semiconductor region includes multiple semiconductor layers having different materials. A capacitance between the first terminal and the third terminal is configured to be adjusted by varying a control voltage applied to at least one of the first terminal or the second terminal.

### TECHNICAL FIELD

Certain aspects of the present disclosure generally relate to electronic circuits and, more particularly, to gallium nitride (GaN)-based variable semiconductor capacitors.

### BACKGROUND

A variable capacitor is a capacitor whose capacitance may be altered, for example, due to a control voltage. Also referred to as a varactor, a variable capacitor may be used in any of various applications where there is a desire to adjust a capacitance, such as in inductor-capacitor (LC) circuits to set the resonance frequency of an oscillator (e.g., radio frequency channel tuning), or as a variable reactance (e.g., for impedance matching in antenna tuners).

A voltage-controlled oscillator (VCO) is an example circuit that may use a varactor in which the thickness of a depletion region formed in a p-n junction diode is varied by changing a bias voltage to alter the junction capacitance. Any junction diode exhibits this effect (including p-n junctions in transistors), but devices used as variable capacitance diodes are designed with a large junction area and a doping profile specifically chosen to improve the device performance, such as quality factor and tuning range.

More recently, variable semiconductor capacitor devices have been developed. These devices may be also be referred to as transcap (TC) devices. The structure of these devices provides a variable semiconductor capacitor with a metal-oxide-semiconductor (MOS)-compatible structure suitable for integrated circuits, which has at least three terminals, one of which is used to modulate the capacitance value between the other two terminals of the device, by increasing or decreasing its direct current (DC) voltage with respect to one of the main terminals of the device.

### SUMMARY

Certain aspects of the present disclosure provide a semiconductor variable capacitor. The semiconductor variable capacitor generally includes a first semiconductor region having a first doping type, a second semiconductor region having a second doping type different from the first doping type, a third semiconductor region disposed between the first semiconductor region and the second semiconductor region, a first terminal disposed adjacent to the first semiconductor region, a second terminal disposed adjacent to the second semiconductor region, and a third terminal disposed above the third semiconductor region. At least one of the first semiconductor region, the second semiconductor region, or the third semiconductor region includes gallium nitride (GaN). The third semiconductor region includes a first semiconductor layer and a second semiconductor layer disposed above the first semiconductor layer. The first semiconductor layer includes a different material than the second semiconductor layer. A capacitance between the first terminal and the third terminal is configured to be adjusted by varying a control voltage applied to at least one of the first terminal or the second terminal.

Certain aspects of the present disclosure provide a method for fabricating a semiconductor variable capacitor. The method generally includes forming a first semiconductor region having a first doping type, forming a second semiconductor region having a second doping type different from the first doping type, forming a third semiconductor region between the first semiconductor region and the second semiconductor region, forming a first terminal adjacent to the first semiconductor region, forming a second terminal adjacent to the second semiconductor region, and forming a third terminal disposed above the third semiconductor region. At least one of the first semiconductor region, the second semiconductor region, or the third semiconductor region includes gallium nitride (GaN). Forming the third semiconductor region includes forming a first semiconductor layer having a first material and forming a second semiconductor layer having a second material different from the first material above the first semiconductor layer. A capacitance between the first terminal and the third terminal is configured to be adjusted by varying a control voltage applied to at least one of the first terminal or the second terminal.

### BRIEF DESCRIPTION OF THE DRAWINGS

So that the manner in which the above-recited features of the present disclosure can be understood in detail, a more particular description, briefly summarized above, may be by reference to aspects, some of which are illustrated in the appended drawings. It is to be noted, however, that the appended drawings illustrate only certain typical aspects of this disclosure and are therefore not to be considered limiting of its scope, for the description may admit to other equally effective aspects.

FIG. 1 illustrates a cross-sectional view of an example variable capacitor.

FIG. 2 illustrates a cross-sectional view of an example structure of a gallium nitride (GaN)-based variable capacitor, in accordance with certain aspects of the present disclosure.

FIG. 3 illustrates a cross-sectional view of an example structure of a GaN-based variable capacitor, in which all terminals are disposed adjacent to a semiconductor region, in accordance with certain aspects of the present disclosure.

FIG. 4 illustrates a cross-sectional view of an example structure of a GaN-based variable capacitor with a semiconductor region that includes a single semiconductor layer, in accordance with certain aspects of the present disclosure.

FIG. 5 illustrates a cross-sectional view of an example structure of a GaN-based variable capacitor having a region of dense electrons between two different bandgap semiconductor regions, in accordance with certain aspects of the present disclosure.

FIG. 6 illustrates a cross-sectional view of an another example structure of a GaN-based variable capacitor having a region of dense electrons between two different bandgap semiconductor regions, in accordance with certain aspects of the present disclosure.

FIG. 7 is a flow diagram of example operations for fabricating a GaN-based variable capacitor, in accordance with certain aspects of the present disclosure.

### DETAILED DESCRIPTION

Aspects of the present disclosure provide semiconductor variable capacitor devices, also referred to as transcap (TC) devices, suitable for integrated circuits. A TC device may have at least three terminals, where the capacitance between two main terminals of the device (C1 and C2) can be varied by changing a voltage applied between a control terminal (CTRL) and one of the other two main terminals (e.g., C1 or C2). Certain aspects of the present disclosure are generally directed to a TC device structure based on a gallium nitride (GaN) material system, e.g., for tuning of GaN-based devices.

The following description provides examples, and is not limiting of the scope, applicability, or embodiments set forth in the claims. Changes may be made in the function and arrangement of elements discussed without departing from the scope of the disclosure. Various examples may omit, substitute, or add various procedures or components as appropriate. For instance, the methods described may be performed in an order different from that described, and various steps may be added, omitted, or combined. Also, features described with respect to some examples may be combined in some other examples. For example, an apparatus may be implemented or a method may be practiced using any number of the aspects set forth herein. In addition, the scope of the disclosure is intended to cover such an apparatus or method that is practiced using other structure, functionality, or structure and functionality in addition to, or other than, the various aspects of the disclosure set forth herein. It should be understood that any aspect of the disclosure disclosed herein may be embodied by one or more elements of a claim.

The word “exemplary” is used herein to mean “serving as an example, instance, or illustration.” Any aspect described herein as “exemplary” is not necessarily to be construed as preferred or advantageous over other aspects.

As used herein, the term “connected with” in the various tenses of the verb “connect” may mean that element A is directly connected to element B or that other elements may be connected between elements A and B (i.e., that element A is indirectly connected with element B). In the case of electrical components, the term “connected with” may also be used herein to mean that a wire, trace, or other electrically conductive material is used to electrically connect elements A and B (and any components electrically connected there between).

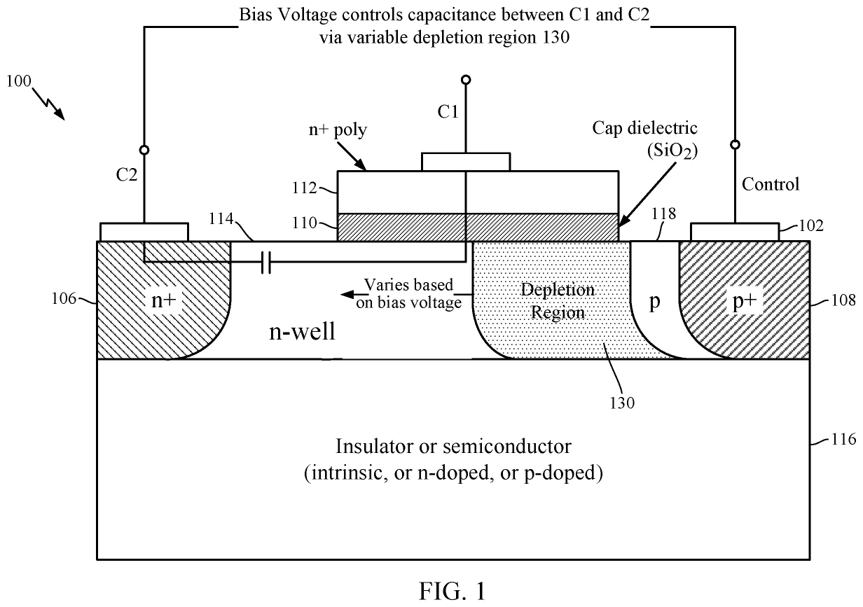

FIG. 1 depicts a cross-sectional view of an example structure of a TC device 100. Certain implementations of a TC device use an oxide layer 110, which may be similar to oxide layers used to fabricate metal-oxide-semiconductor (MOS) devices (e.g., thin or thick gate oxide). The oxide layer 110 isolates the C1 and C2 terminals, and thus, in effect acts as a dielectric for TC device 100. A non-insulative region 106 (e.g., an n+ implantation region) and a non-insulative region 108 (e.g., a p+ implantation region) may be formed on the two sides of the TC device 100 in order to create p-n junctions. As used herein, a non-insulative region generally refers to a region that may be electrically conductive or semiconductive.

In one example, a bias voltage may be applied between the control terminal 102 and the C2 terminal in order to modulate the capacitance between terminals C1 and C2. For example, by applying a bias voltage to the control terminal 102, a depletion region 130 may be formed at the p-n junction between the non-insulative region 108 (e.g., control region) and a semiconductor region 114 (e.g., n-well region). Based on the bias voltage, this depletion region 130 may widen under the oxide layer 110, reducing the area of the equivalent electrode formed by the semiconductor region 114, and thereby also reducing the effective capacitance area and capacitance value of TC device 100.

The work-function of a non-insulative region 112 above the oxide layer 110 may be chosen to improve the device performance. For example, an n-doped poly-silicon material may be used (instead of p-doped) for non-insulative region 112, even if the semiconductor region 114 underneath the oxide layer 110 is doped with n-type impurities. In some aspects, a metallic material (also doped if desired) with an opportune work-function or a multi-layer stack of different metallic materials may be used for the non-insulative region 112, so as to obtain the desired work-function. In certain aspects, the non-insulative region 112 may be divided into two sub-regions (e.g., one n-doped and one p-doped), or a different metallic material may be used for each sub-region.

In some cases, the semiconductor region 114 may be disposed above an insulator or semiconductor region 116. The type of material for the semiconductor region 116 may be chosen in order to improve the TC device 100 performance. For example, the semiconductor region 116 may be an insulator, a semi-insulator, or an intrinsic/near-intrinsic semiconductor in order to decrease the parasitic capacitances associated with the substrate (not shown). In some cases, the semiconductor region 116 can be made of n-doped or p-doped semiconductor with an appropriate doping profile in order to increase the TC device quality factor and/or the control on the depletion region 130 that may be formed between the non-insulative region 108 and the semiconductor region 114 when applying a bias voltage to the control terminal 102. The semiconductor region 116 can also be formed by multiple semiconductor layers or regions doped in different ways (n, p, or intrinsic). Furthermore, the semiconductor region 116 may include semiconductors, insulating layers, and/or substrates or can be formed above semiconductors, insulating layers, and/or substrates.

The width of the depletion region 130 in the semiconductor region 114 may be controlled by applying a control voltage to the control terminal 102. As a reference example, the control terminal 102 may be biased with a negative voltage with respect to the C2 terminal. The capacitance between the C1 and C2 terminals may depend on the dimensions of the depletion region 130 in the semiconductor region 114, and thus, can be controlled by applying the control voltage to the control terminal 102. Furthermore, the variation of the bias voltage applied to the control terminal 102 may not alter the DC voltage between the C1 and C2 terminals, allowing for improved control of the device characteristics.

In some cases, it may be preferable to locate the non-insulative region 106 and/or non-insulative region 108 away from the oxide layer 110 in order to reduce the parasitic capacitance associated with the non-insulative region 108 and increase the isolation of the non-insulative region 106 for high control voltages. For example, the non-insulative region 106 can be partially overlapped by the oxide layer 110, or the non-insulative region 106 can be formed at a distance from the edge of the oxide layer 110 so as to increase the device tuning range and linearity. In the latter case, the voltage-withstanding capability of the device is increased since a portion of a signal (e.g., radio frequency (RF) signal) applied to the C1 and C2 terminals drops between the oxide edge and the non-insulative region 106 instead of being applied entirely across the oxide layer 110.

The non-insulative region 108 can be partially overlapped by the oxide layer 110, or the non-insulative region 108 can be spaced apart therefrom so as to reduce the parasitic capacitance between the C1 terminal and the control terminal 102.

A p-doped region 118 can be optionally used to increase the breakdown voltage of the p-n junction between the non-insulative region 108 and the semiconductor region 114, decreasing, at the same time, the parasitic capacitance between the C1 terminal and the control terminal 102. Similarly, an optional n-doped region (not shown) can be added between the non-insulative region 106 and the semiconductor region 114 in order to regulate the doping concentration between the oxide layer 110 and the non-insulative region 106.

Some of the focus of the development of fifth generation of wireless systems (5G) (or next generation) technology has been improving device performance and efficiency, e.g., compared to fourth generation (4G) (also known as Long Term Evolution (LTE)) devices. As a reference example, 5G devices in general may be expected to be more efficient, have higher capacity, and/or be capable of communications with lower latency, compared to 4G devices. GaN has recently emerged as an excellent candidate material that can meet these objectives for 5G devices (e.g., high performance radio frequency front-end (RFFE), power electronic chips, millimeter wave (mmW) circuits, etc.). For example, compared to silicon (Si) and other III-V materials, GaN typically has a higher bandgap, higher electron peak velocity, higher breakdown electric field, higher Johnson Figure of Merit (FOM), higher Baliga FOM, etc. In addition, GaN offers superior properties in high power density, power added efficiency (PAE), gain, and ease in impedance matching, which improves overall efficiency in the RF chain.

It may be desirable to provide capacitance tuning capabilities to 5G RF designs based on GaN. For example, power amplifier (PA) tuning can optimize, or at least adjust, the matching circuitry for higher efficiency and output power. However, conventional transcap devices (e.g., TC device 100) are typically Si complementary metal-oxide-semiconductor (CMOS)-based transcap devices, which may not be suitable for GaN and/or aluminum gallium nitride (AlGaN) material systems. For example, Si CMOS-based transcap devices may have a low quality factor (Q) due to low mobility and high resistance. Further, it may be difficult to integrate Si CMOS-based transcap devices into a GaN PA die.

Certain aspects of the present disclosure provide various semiconductor variable capacitors built with GaN material that can be easily integrated with GaN-based transistor devices. For example, the GaN-based TC devices described herein can be used for tuning in RFFE, power electronic chips, mmW circuits, etc.

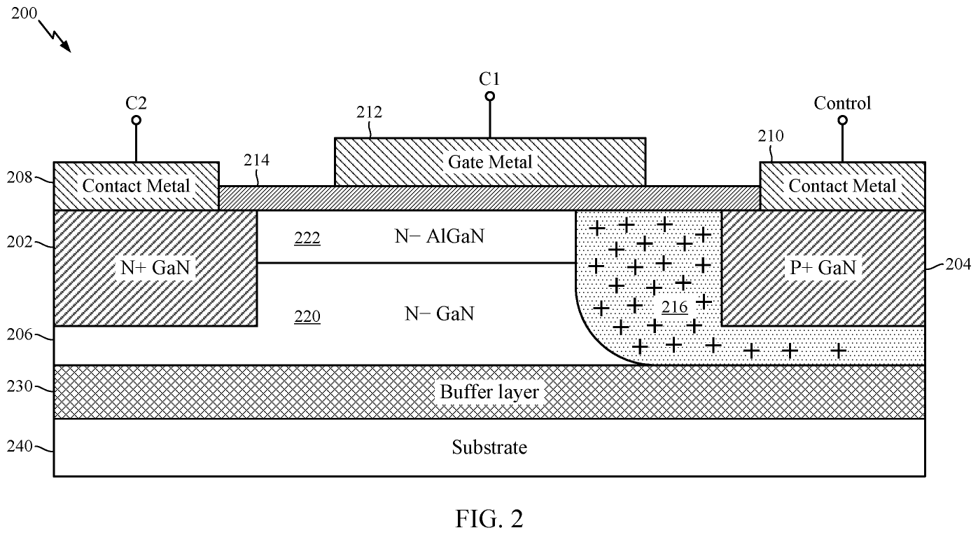

FIG. 2 illustrates a cross-sectional view of an example structure of a TC device 200, in accordance with certain aspects of the present disclosure. The TC device 200 includes a semiconductor region 202 (e.g., with n+ doped GaN) and a semiconductor region 204 (e.g., with p+ doped GaN). A C2 terminal (e.g., metallic contact) 208 is disposed on or above the semiconductor region 202, and a control terminal (e.g., metallic contact) 210 is disposed on or above the semiconductor region 204. The TC device 200 also includes a semiconductor region 206 (with n− doping) disposed on or above a buffer layer 230 and disposed between semiconductor region 202 and semiconductor region 204.

A C1 terminal (e.g., gate metal) 212 is disposed on a (e.g., thin) dielectric layer 214, which is disposed on or above the semiconductor region 206 and disposed between the C2 terminal 208 and the control terminal 210. In some aspects, the dielectric layer 214 may have a thickness between 1 nanometer (nm) to 10 nm, for example. The dielectric layer 214 may include any of various suitable dielectric materials, such as silicon monoxide (SiO), silicon mononitride (SiN), aluminum monoxide (AlO), etc. A buffer layer 230 may be provided between the semiconductor region 206 and a substrate 240. In some aspects, the buffer layer 230 may include GaN. The substrate 240 may include any of various suitable materials for growing GaN, such as Si, silicon carbide (SiC), aluminum oxide (Al₂O₃), etc.

One or more of semiconductor regions 202, 204, and 206 may include GaN. As shown in this example, each of semiconductor regions 202, 204, and 206 includes GaN. Semiconductor region 206 may include multiple semiconductor layers with different materials for, for example, easier integration with GaN-based devices. Including multiple semiconductor layers may also increase the tuning range of the TC device 200, e.g., relative to TC devices with a single semiconductor layer. As shown, semiconductor region 206 includes a semiconductor layer 220 (disposed on buffer layer 230) that includes GaN with n− doping, and a semiconductor layer 222 (disposed on semiconductor layer 220) that includes AlGaN with n− doping. The semiconductor regions 202 and 204 may be disposed above at least a portion of semiconductor region 206 (e.g., at least a portion of semiconductor layer 220).

A depletion region 216 may form at the p-n junction between the semiconductor region 206 and semiconductor region 204 by applying a control voltage to control terminal 210 (or C2 terminal 208) with respect to the C1 terminal 212. Based on the control voltage, the depletion region 216 may widen or narrow under the C1 terminal 212, allowing for the capacitance between the C1 terminal 212 and the C2 terminal 208 to be adjusted.

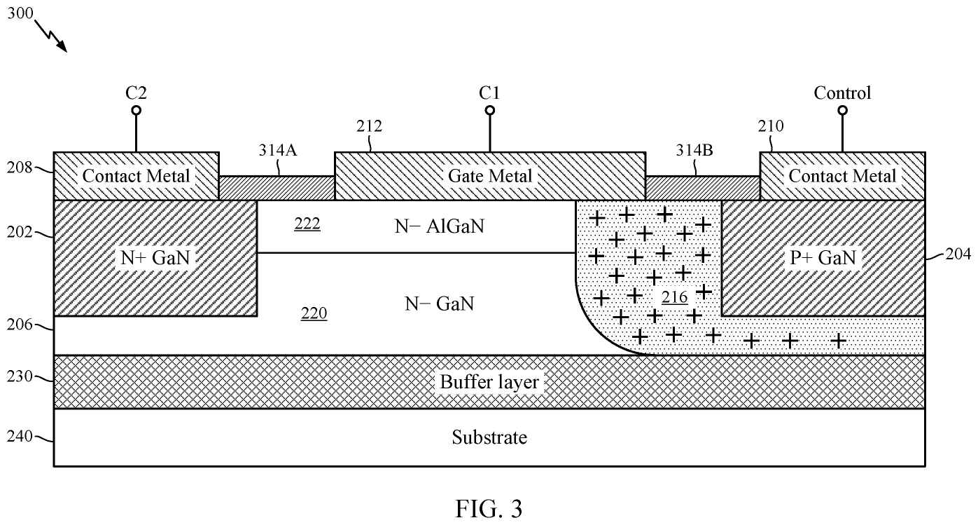

FIG. 3 illustrates a cross-sectional view of an example structure of a TC device 300, in accordance with certain aspects of the present disclosure. Here, similar to the TC device 200 of FIG. 2, a semiconductor region 206 (with n− doping) is disposed between a semiconductor region 202 (e.g., with n+ doped GaN) and a semiconductor region 204 (e.g., with p+ doped GaN), where a C2 terminal 208 is disposed on or above the semiconductor region 202 and a control terminal 210 is disposed on or above the semiconductor region 204. However, contrary to the TC device 200 of FIG. 2, the C1 terminal 212 is disposed directly on the semiconductor region 206 (which includes semiconductor layer 222 and semiconductor layer 220). Further, TC device 300 includes a dielectric layer disposed on the semiconductor region 206, where a first portion 314A of the dielectric layer is disposed between the C2 terminal 208 and the C1 terminal 212, and a second portion 314B of the dielectric layer is disposed between the C1 terminal 212 and the control terminal 210. The TC device 300 may have improved compatibility with Schottky gate processes for GaN-based transistors (e.g., compared to the TC device 200), which may further facilitate integration with GaN-based transistor devices, reduce cost, etc.

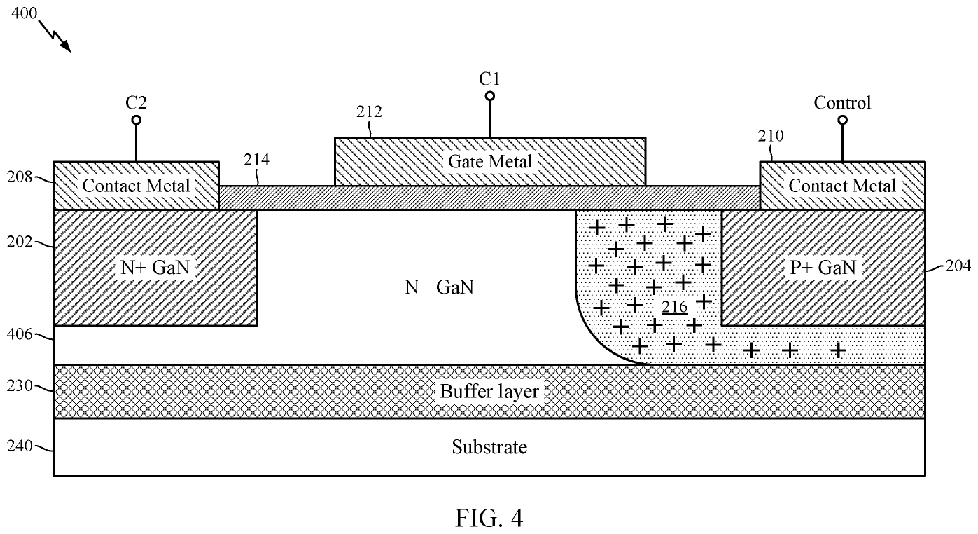

FIG. 4 illustrates a cross-sectional view of an example structure of a TC device 400, in accordance with certain aspects of the present disclosure. Here, similar to the TC device 200 of FIG. 2, a semiconductor region with GaN (e.g., semiconductor region 406) is disposed between a semiconductor region 202 (e.g., with n+ doped GaN) and a semiconductor region 204 (e.g., with p+ doped GaN). However, contrary to the TC device 200 of FIG. 2, the semiconductor region (e.g., semiconductor region 406) disposed between semiconductor region 202 and semiconductor region 206 includes a single layer (e.g., with n− doped GaN), as opposed to multiple layers. In some aspects, the semiconductor region 406 may be formed by etching away the semiconductor layer that includes AlGaN (e.g., semiconductor layer 222). In some aspects, removing the additional layer(s) may reduce the tuning range of the TC device 400, e.g., compared to TC device 200.

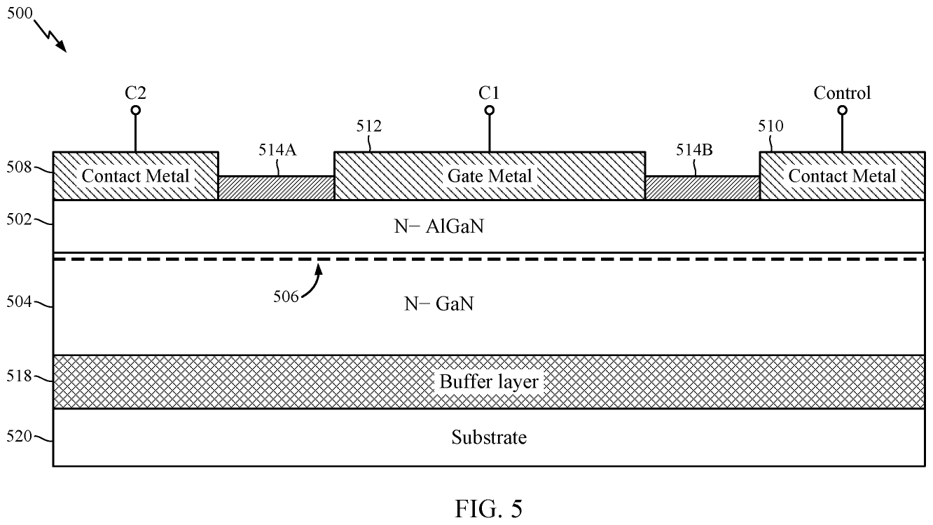

FIG. 5 illustrates a cross-sectional view of an example structure of a TC device 500, in accordance with certain aspects of the present disclosure. The TC device 500 includes a semiconductor region 504 (e.g., with n− doped GaN) disposed above a buffer layer 518, which is disposed above a substrate 520. Buffer layer 518 and substrate 520 may be similar to buffer layer 230 and substrate 240, respectively, of the TC device 200 illustrated in FIG. 2. A semiconductor region 502 (e.g., with n− doped AlGaN) is disposed above semiconductor region 504. As shown, the TC device 500 further includes a region 506 of very dense electrons between the semiconductor region 502 and the semiconductor region 504. The region 506 enables the TC device 500 to have a high electron density (or high conductivity) at the interface between the semiconductor region 502 and the semiconductor region 504.

A C2 terminal (e.g., metallic contact) 508, a C1 terminal (e.g., gate metal) 512, and a control terminal (e.g., metallic contact) 510 are disposed (e.g., directly) on the semiconductor region 502. The TC device 500 further includes a dielectric layer disposed on the semiconductor region 502, where a first portion 514A of the dielectric layer is disposed between the C2 terminal 508 and the C1 terminal 512, and a second portion 514B is disposed between the C1 terminal 512 and the control terminal 510.

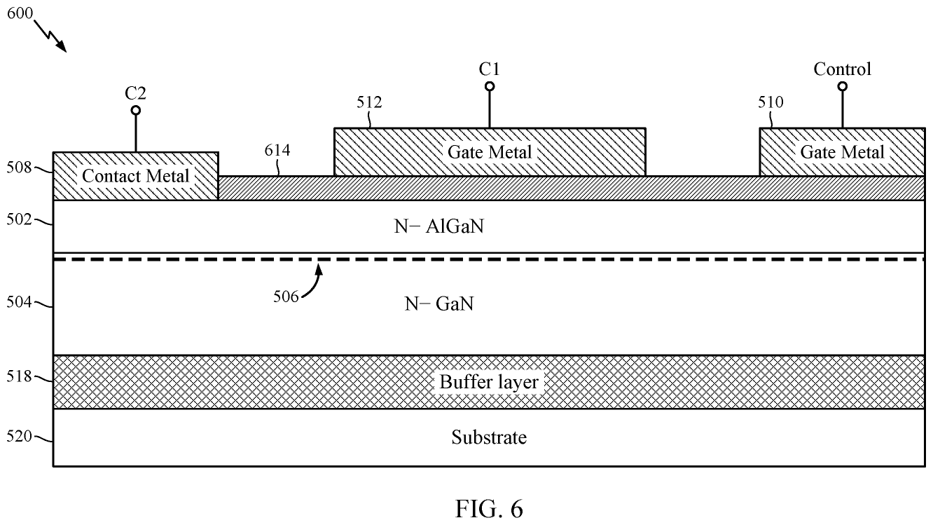

FIG. 6 illustrates a cross-sectional view of an example structure of a TC device 600, in accordance with certain aspects of the present disclosure. Here, similar to the TC device 500 of FIG. 5, the TC device 600 includes a semiconductor region 504 (e.g., with n− doped GaN) disposed on a buffer layer 518, a semiconductor region 502 (e.g., with n− doped AlGaN) disposed above the semiconductor region 504, and a region 506 of dense electrons at the interface between the semiconductor region 502 and the semiconductor region 504. However, contrary to the TC device 500 of FIG. 5, the C1 terminal 510 and the control terminal 512 are disposed on a dielectric layer 614, which is disposed on the semiconductor region 502. The C2 terminal 508 is disposed on or above the semiconductor region 502 and adjacent to the dielectric layer 614.

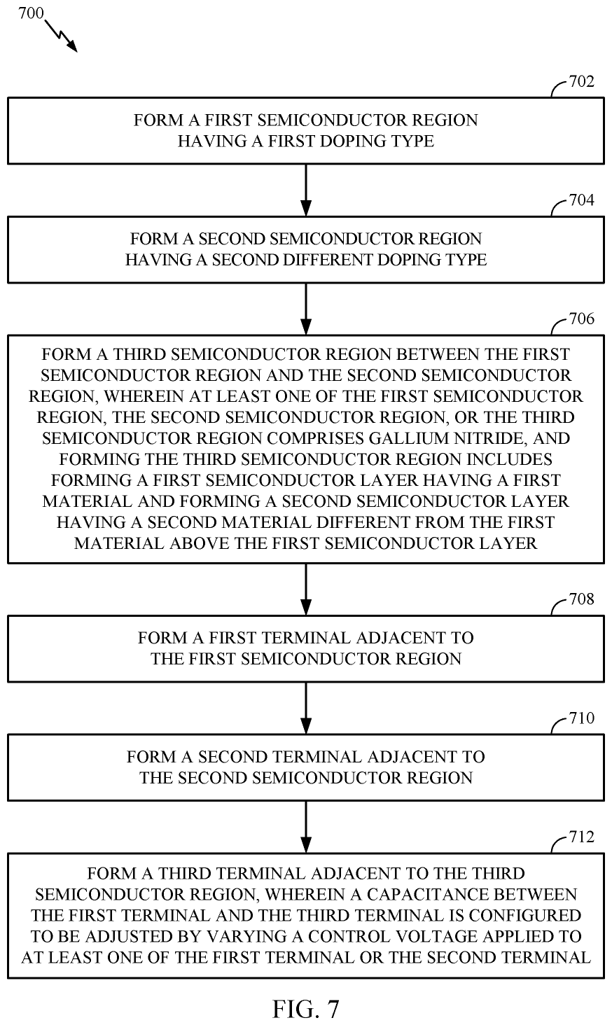

FIG. 7 is a flow diagram of example operations 700 for fabricating a semiconductor variable capacitor, in accordance with certain aspects of the present disclosure. The operations 700 may be performed, for example, by a semiconductor processing chamber.

Operations 700 may begin, at block 702, by forming a first semiconductor region (e.g., semiconductor region 202) having a first doping type (e.g., n+ doping). At block 704, a second semiconductor region (e.g., semiconductor region 204) having a second doping type (e.g., p+ doping) different from the first doping type is formed. At block 706, a third semiconductor region (e.g., semiconductor region 206) is formed between the first semiconductor region and the second semiconductor region.

In some aspects, at least one of the first semiconductor region, the second semiconductor region, or the third semiconductor region may include GaN. In some aspects, the third semiconductor region may be formed by forming a first semiconductor layer (e.g., semiconductor layer 220) having a first material (e.g., GaN) and forming a second semiconductor layer (e.g., semiconductor layer 222) having a second material (e.g., AlGaN) different from the first material above the first semiconductor layer. In some aspects, the first semiconductor region and the second semiconductor region may be formed above at least a portion of the third semiconductor region.

At block 708, a first terminal (e.g., C2 terminal) is formed adjacent to the first semiconductor region. At block 710, a second terminal (e.g., control terminal 210) is formed adjacent to the second semiconductor region. At block 712, a third terminal (e.g., C1 terminal) is formed above the third semiconductor region. A capacitance between the first terminal and the third terminal is configured to be adjusted by varying a control (e.g., bias) voltage applied to at least one of the first terminal or the second terminal.

In some aspects, operations 700 may include forming a substrate (e.g., substrate 240), and forming a buffer layer (e.g., buffer layer 230) above the substrate and below the third semiconductor region. In some aspects, operations 700 may include forming a dielectric layer (e.g., dielectric layer 214) adjacent to the third semiconductor region, below the third terminal, and between the first terminal and the second terminal.

In some aspects, operations 700 may include forming the third terminal directly adjacent to at least a first portion of the third semiconductor region. In these aspects, a dielectric layer may be formed adjacent to at least a second portion of the third semiconductor region, where a first portion (e.g., 314A) of the dielectric layer is disposed between the first terminal and the third terminal, and a second portion (e.g., 314B) of the dielectric layer is disposed between the third terminal and the second terminal.

The various operations of methods described above may be performed by any suitable means capable of performing the corresponding functions. The means may include various hardware and/or software component(s) and/or module(s), including, but not limited to a circuit, an application-specific integrated circuit (ASIC), or processor. Generally, where there are operations illustrated in figures, those operations may have corresponding counterpart means-plus-function components with similar numbering.

As used herein, the term “determining” encompasses a wide variety of actions. For example, “determining” may include calculating, computing, processing, deriving, investigating, looking up (e.g., looking up in a table, a database, or another data structure), ascertaining, and the like. Also, “determining” may include receiving (e.g., receiving information), accessing (e.g., accessing data in a memory), and the like. Also, “determining” may include resolving, selecting, choosing, establishing, and the like.

As used herein, a phrase referring to “at least one of” a list of items refers to any combination of those items, including single members. As an example, “at least one of: a, b, or c” is intended to cover: a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, and c-c-c or any other ordering of a, b, and c).

The methods disclosed herein comprise one or more steps or actions for achieving the described method. The method steps and/or actions may be interchanged with one another without departing from the scope of the claims. In other words, unless a specific order of steps or actions is specified, the order and/or use of specific steps and/or actions may be modified without departing from the scope of the claims.

It is to be understood that the claims are not limited to the precise configuration and components illustrated above. Various modifications, changes and variations may be made in the arrangement, operation and details of the methods and apparatus described above without departing from the scope of the claims.

What is claimed is:

1. A semiconductor capacitor comprising:
a first semiconductor region comprising n+ doped gallium nitride (GaN);
a second semiconductor region comprising p+ doped GaN;
a third semiconductor region disposed between the first semiconductor region and the second semiconductor region, wherein:
the third semiconductor region comprises a first semiconductor layer and a second semiconductor layer disposed above the first semiconductor layer; and
the first semiconductor layer comprises a different material than the second semiconductor layer;
a first terminal disposed adjacent to the first semiconductor region;
a second terminal disposed adjacent to the second semiconductor region; and
a third terminal disposed above the third semiconductor region, wherein a capacitance between the first terminal and the third terminal is configured to be adjusted by varying a control voltage applied to at least one of the first terminal or the second terminal.

2. The semiconductor capacitor of claim 1, wherein the first semiconductor region and the second semiconductor region are disposed above at least a portion of the third semiconductor region.

3. (canceled)

4. The semiconductor capacitor of claim 1, wherein the third semiconductor region comprises n− doped GaN.

5. (canceled)

6. The semiconductor capacitor of claim 1, wherein:
the first semiconductor layer of the third semiconductor region comprises n− doped GaN; and
the second semiconductor layer of the third semiconductor region comprises n− doped aluminum gallium nitride (AlGaN).

7. (canceled)

8. The semiconductor capacitor of claim 1, further comprising a dielectric layer disposed adjacent to the third semiconductor region, below the third terminal, and between the first terminal and the second terminal.

9. The semiconductor capacitor of claim 8, wherein the dielectric layer comprises silicon monoxide (SiO), silicon mononitride (SiN), or aluminum monoxide (AlO).

10. The semiconductor capacitor of claim 1, wherein the third terminal is further disposed directly adjacent to at least a first portion of the third semiconductor region.

11. The semiconductor capacitor of claim 10, further comprising a dielectric layer being disposed adjacent to at least a second portion of the third semiconductor region, wherein:
a first portion of the dielectric layer is disposed between the first terminal and the third terminal; and
a second portion of the dielectric layer is disposed between the third terminal and the second terminal.

12. The semiconductor capacitor of claim 1, further comprising:
a substrate; and
a buffer layer disposed above the substrate and below the third semiconductor region.

13. The semiconductor capacitor of claim 12, wherein the buffer layer comprises GaN.

14. The semiconductor capacitor of claim 12, wherein the substrate comprises silicon (Si), silicon carbide (SiC), or aluminum oxide (Al₂O₃).

15. A method for fabricating a semiconductor capacitor, comprising:
forming a first semiconductor region having n+ doped gallium nitride (GaN);
forming a second semiconductor region having p+ doped GaN;
forming a third semiconductor region between the first semiconductor region and the second semiconductor region, comprising forming a first semiconductor layer having a first material and forming a second semiconductor layer having a second material different from the first material above the first semiconductor layer;
forming a first terminal adjacent to the first semiconductor region;
forming a second terminal adjacent to the second semiconductor region; and
forming a third terminal disposed above the third semiconductor region, wherein a capacitance between the first terminal and the third terminal is configured to be adjusted by varying a control voltage applied to at least one of the first terminal or the second terminal.

16. The method of claim 15, wherein the first semiconductor region and the second semiconductor region are formed above at least a portion of the third semiconductor region.

17. (canceled)

18. The method of claim 15, wherein the third semiconductor region comprises n− doped GaN.

19. (canceled)

20. The method of claim 15, wherein:
the first semiconductor layer of the third semiconductor region comprises n− doped GaN; and
the second semiconductor layer of the third semiconductor region comprises n− doped aluminum gallium nitride (AlGaN).

21. (canceled)

22. The method of claim 15, further comprising forming a dielectric layer adjacent to the third semiconductor region, below the third terminal, and between the first terminal and the second terminal.

23. The method of claim 22, wherein the dielectric layer comprises silicon monoxide (SiO), silicon mononitride (SiN), or aluminum monoxide (AlO).

24. The method of claim 15, wherein the third terminal is formed further directly adjacent to at least a first portion of the third semiconductor region.

25. The method of claim 24, further comprising forming a dielectric layer adjacent to at least a second portion of the third semiconductor region, wherein:
a first portion of the dielectric layer is disposed between the first terminal and the third terminal; and
a second portion of the dielectric layer is disposed between the third terminal and the second terminal.

26. The method of claim 15, further comprising:
forming a substrate; and
forming a buffer layer above the substrate and below the third semiconductor region.

27. The method of claim 26, wherein the buffer layer comprises GaN.

28. The method of claim 26, wherein the substrate comprises silicon (Si), silicon carbide (SiC), or aluminum oxide (Al₂O₃).
